(19) United States
(12) Patent Application Publication
(10) Pub. No.: US 2025/0199481 A1
(43) Pub. Date: Jun. 19, 2025

(54) METHOD FOR MANUFACTURING WATCH COMPONENTS IN BATCHES

(71) Applicant: Nivarox-FAR S.A., Le Locle (CH)

(72) Inventors: Fatmir SALIHU, Neuchatel (CH); Philippe BARFUSS, Auvernier (CH); Pierre CUSIN, Villars-Burquin (CH)

(73) Assignee: Nivarox-FAR S.A., Le Locle (CH)

(21) Appl. No.: 18/937,106

(22) Filed: Nov. 5, 2024

(30) Foreign Application Priority Data
Dec. 18, 2023 (EP) 23217455.7

(51) Int. Cl. G04D 3/00; C25D 1/00; C25D 5/02

(52) U.S. Cl. CPC G04D 3/0069; C25D 1/003; C25D 5/022; G04D 3/0074

(57) ABSTRACT

A method for manufacturing watch components in batches.

### TECHNICAL FIELD OF THE INVENTION

This invention relates to a method for manufacturing a batch of metallic watch components using the LIGA technology.

### TECHNOLOGICAL BACKGROUND

Methods corresponding to the above definition are already known. In particular, the article by A. B. Frazier et al. entitled “Metallic Microstuctures Fabricated Using Photosensitive Polyimide Electroplating moulds” and published in the Journal of Microelectromechanical systems (Vol. 2, N deg. 2, June 1993) describes a method for manufacturing multi-level metallic structures by galvanic growth in polyimide moulds made by photolithography of photosensitive resin layers.

This method comprises the following steps:
creating on a substrate a sacrificial metal layer and a primer layer for a subsequent galvanic growth step,
applying a layer of photosensitive polyimide,
irradiating the polyimide layer with UV radiation through a mask corresponding to the outline of a level of the structure to be obtained,
developing the polyimide layer by dissolving the non-irradiated portions so as to obtain a polyimide mould,
filling the mould with nickel up to its height by galvanic growth, and obtaining a substantially planar upper surface,
depositing a thin layer of chromium over the entire upper surface by vacuum spraying,
depositing a new layer of photosensitive resin over the chromium layer,
irradiating the resin layer through a new mask corresponding to the outline of the next level of the structure to be obtained,
developing the polyimide layer so as to obtain a new mould,
filling the new mould with nickel up to its height by galvanic growth,
separating the multi-level structure and the polyimide mould from the sacrificial layer and the substrate,
separating the multi-level structure of the polyimide mould.

It should be understood that the method just described could, in principle, be implemented iteratively to obtain metal structures with more than two levels.

The drawback of such a method is that many parts are manufactured in bulk, which might lead to deterioration of the parts due to impacts, jamming or entanglement. To overcome this drawback, it is possible to sort the parts, but this is costly and time-consuming.

Another drawback of such a method is that when it is necessary to perform one or more finishing step(s), a complex positioning is required to position the individual parts correctly during the operation. The parts then have to be reordered for each finishing stage, which is also costly and time-consuming.

### SUMMARY OF THE INVENTION

The invention solves the aforementioned drawbacks by providing a solution for keeping components attached to each other via a grid, so that they can be handled, worked on and/or decorated in batches.

The invention also allows keeping the components attached to the grid like on a wafer, while clearing the rear face so that it can be worked on and/or decorated easily without having to implement complex technical means to keep the components positioned individually, while turning them over to carry out a rear face operation. Once the components have been turned over, accurate positioning is essential for carrying out the intended mechanical rework operation.

To this end, the present invention relates to a method for manufacturing watch components in batches, characterised in that it comprises the following steps:
a) providing a substrate covered with a conductive priming layer;
b) applying a layer of photosensitive resin to the conductive portion of the surface of the substrate;
c) irradiating the resin layer through a mask defining the outline of a batch of components, as well as a grid and material bridges, the material bridges connecting the components to the grid at a non-functional surface, the grid, the material bridges and the watch components forming a cluster of components;
d) dissolving the non-irradiated areas of the photosensitive resin layer to reveal the conductive surface of the substrate in places and form a mould;
e) conformal electro-galvanic deposition of a metal layer from the conductive layer, the metal layer forming the cluster of components and reaching the level of the upper surface of the photosensitive resin layer;
f) removing the photosensitive resin layer and the substrate to release the cluster of components thus formed;
g) releasing the component from the cluster.

In accordance with other advantageous variants of the invention:
the method comprises a step e′) between step e) and step f), during which the resin layer and the deposited metal layer are planarised to bring the resin layer and the electrodeposited metal layer to the same level.
the method comprises:
   after step d), repeating steps c) and d) at least once to obtain a mould with at least two levels;
   applying at least one other metal layer to the at least second level of the mould.
the mould has several levels;
the material bridge has a thickness identical to that of the component;
the material bridge is thinner than the component;
the method comprises a step g) of wafer finishing of the front, rear and/or side faces of the watch component, the finishing step consisting in depositing layers, for example structuring and/or decorating layers;
the cluster of watch components comprises a batch of the same components selected from: wheel, cam, hand, lever, snail, oscillating weight, index or applique;
the cluster of watch components comprises a batch of different components such as wheels, cams, hands, levers, oscillating weights, snails, indexes or appliques.

The invention also relates to a batch or cluster of watch components obtained by implementing a manufacturing method in accordance with the invention.

### BRIEF DESCRIPTION OF THE FIGURES

Other features and advantages of the invention will become apparent from the following detailed description, which is given as a non-limiting example, with reference to the attached drawings wherein:

FIG. 1 schematically shows the manufacturing process in accordance with the invention;

FIG. 2 illustrates an example of a cluster of components obtained using the method in accordance with the invention.

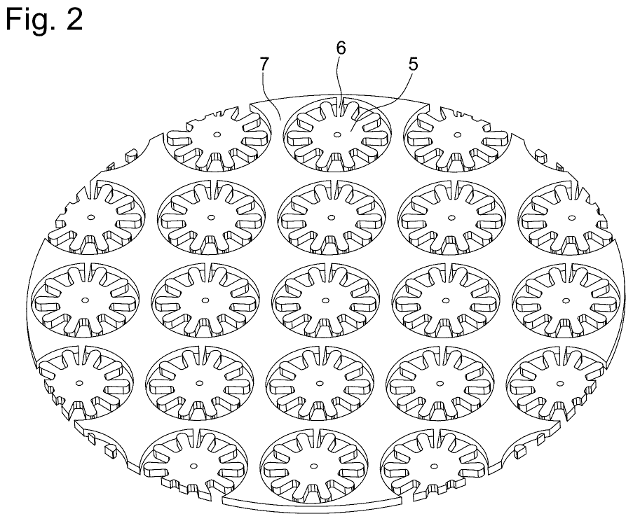

### DETAILED DESCRIPTION OF THE INVENTION

The invention relates to a method for manufacturing a watch component.

By functional outer profile, it should be understood a watch component whose external outline forms a functional surface designed to cooperate with other watch parts and/or components.

The substrate 1 used in step a) of the method according to the invention is, for example, formed by a silicon substrate. During the first step a) of the method, a conductive layer 2 i.e. a layer capable of starting a metal deposit by galvanic means, is deposited, for example by physical vapour deposition (PVD). Typically, the conductive layer 2 is of the Au, Ti, Pt, Ag, Cr or Pd type, or a stack of at least two of these materials, and has a thickness comprised between 50 nm and 500 nm. For example, the conductive layer 2 may be formed from a chromium or titanium sub-layer covered by a layer of gold or copper.

The photosensitive resin 3 used in this method is preferably a negative type resin based on octofunctional epoxy designed to polymerise under the action of UV radiation.

According to a particular embodiment of the invention, the resin is in the form of a dry film, and the resin is then applied by lamination to the substrate 1.

Alternatively, the photosensitive resin could be a positive photoresist which is designed to decompose under the action of UV radiation. It should be understood that the present invention is not limited to a few particular types of photosensitive resin. A person skilled in the art will be able to select a photosensitive resin suitable for his or her needs from all the known resins that are suitable for UV photolithography.

During step b), a layer of resin 3 is deposited over the substrate 1 by any suitable means, by centrifugal coating, spin coating or spraying to the desired thickness. Typically, the resin thickness is between 10 μm and 1,000μm, and preferably between 30 μm and 300 μm. Depending on the desired thickness and the deposition technique used, the first resin layer 3 will be deposited in one or more layer(s).

Afterwards, the first resin layer 3 is heated, typically to between 90and 120° C., for a period depending on the deposited thickness, to remove the solvent (pre-bake stage). This heating dries and hardens the resin.

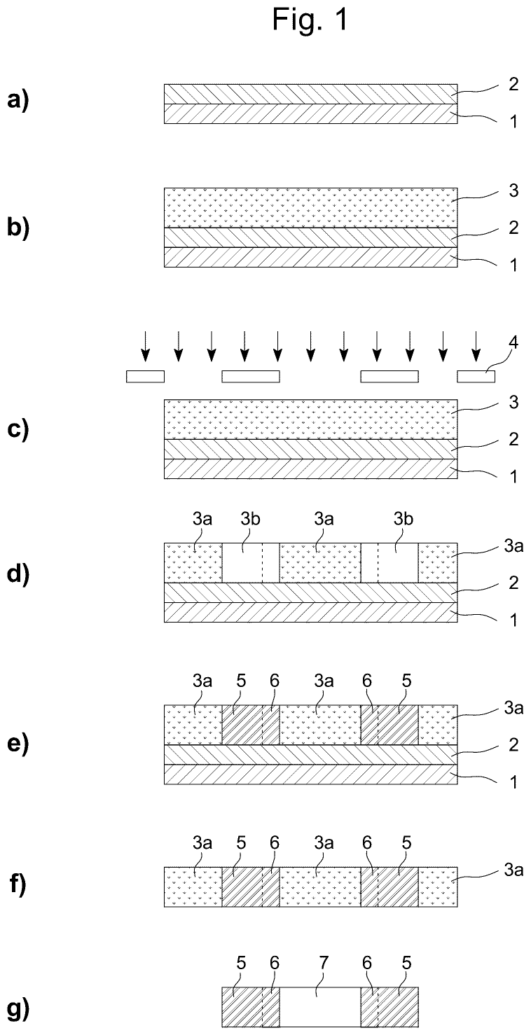

The next step c) illustrated in FIG. 1 consists in irradiating the first resin layer 3 with UV radiation through a mask 4 defining the mould of the component to be formed and thus photopolymerised areas 3a and non-photopolymerised areas 3b.

According to the invention, during step c), the mask allows defining the outline of a batch of components 5, as well as the outlines of a grid 7 and material bridges 6. The material bridges allow connecting the components to the grid at a non-functional surface.

Thus, the grid, the material bridges and the watch components form a cluster of components at the end of the process.

As required by the person skilled in the art, the grid and/or the material bridges are thinner than the components.

Advantageously, the material bridges connect the components to the grid at a non-functional outer profile of the components. This means a watch component wherein the external outline of the component forms a functional surface designed to cooperate with other watch parts and/or components, a non-functional outer profile (or surface) is therefore, by analogy, a profile that is not likely to cooperate with another component.

A step of annealing (post-bake step) the first resin layer 3 might be necessary to complete the photopolymerisation induced by the UV irradiation. This annealing step is preferably performed between 90° C. and 95° C. The photopolymerised areas 3a become insensitive to most solvents. However, the non-photopolymerised areas could subsequently be dissolved by a solvent.

Afterwards, the non-photopolymerised areas 3b of the first photosensitive resin layer 3 are dissolved to reveal the conductive layer 2 of the substrate 1 in places. This operation is carried out by dissolving the non-photopolymerised areas 3b using a suitable solvent, such as PGMEA (propylene glycol methyl ethyl acetate). A mould of photopolymerised photosensitive resin 3a defining the first level of the component is thus made.

The next step d), illustrated in FIG. 1, consists in depositing a layer of a metal from the electrically-conductive layer 2 into the mould by electroforming or galvanic deposition, until a block is formed which preferably reaches a height smaller than the height of the mould, that allowing for better mechanical strength during subsequent machining. The term metal in this context naturally includes metal alloys. Typically, the metal will be selected from the group comprising nickel, copper, gold or silver, and, as an alloy, gold-copper, nickel-cobalt, nickel-iron, nickel-phosphorus or nickel-tungsten.

Optionally, the process comprises a step e′), after step e), which consists in machining, by a mechanical process, the metal layer forming the components 5, and if necessary, the photopolymerised resin layer 3a, to a thickness predefined by the thickness of the component to be made.

Step f) consists in releasing the cluster of components by removing the substrate, the conductive layers and the resin layers in a succession of wet or dry etching steps, which operations are familiar to a person skilled in the art.

For example, the conductive layer 2 and the substrate 1 are removed by wet etching, which allows releasing the cluster of components from the substrate 1 without damaging it. Notably, in the example of a silicon substrate, this can be etched with a potassium hydroxide (KOH) solution.

Upon completion of this first sequence, a cluster of components is obtained embedded in the resin layer as illustrated in step g).

A 2nd sequence consists of removing the first layer 3 and the second layer 6 of resin by means of O2 plasma etching, spaced apart from wet etching of the intermediate metal layers.

Afterwards, the method may comprise a step that consists in carrying out mechanical machining operations such as chamfering the edges of the visible face of the component, for example, or threading or countersinking the component. The operations will obviously depend on the geometry of the final component to be obtained.

Upon completion of this step, the cluster of components obtained may be cleaned, and the components of the cluster, still secured to the cluster, may be subjected to various decorative and/or functional treatments, typically physical or chemical deposits.

The components may undergo various surface finishing operations while still held to the cluster by the clamp accurately and easily. Thus, the front, rear and/or side faces of the watch component could be worked on while the component is still held to the wafer. The finishing step may consist in depositing layers, structuring or decorating layers, over the different faces of the watch component. These operations may be functional (reinforcement, tribological, etc.) or aesthetic (colouring, pattern), using PVD or CVD.

Finally, the last step consists in releasing the component(s) from the formed cluster. The components may be separated from the cluster using different methods, such as laser cutting, stamping or mechanical breaking.

According to an optional step, after step b), the resin layer 3 is machined to thickness. Advantageously, this operation allows finely controlling the geometry of the parts to the scale of the substrate 1. Once the resin has been thickened, a heat treatment is carried out to eliminate the traces of machining.

The above example has been written for single-level components. The method may also be applied to components with several levels or stages.

To do so, a multi-level mould is made by depositing at least one second conductive layer over the photopolymerised areas 3a in step c). This second conductive layer may have the same characteristics as the first conductive layer 2, namely that it is of the Au, Ti, Pt, Ag, Cr, Pd type or a stack of at least two of these materials, and has a thickness comprised between 50 nm and 500 nm.

Afterwards, a new layer of photosensitive resin is deposited over the second conductive layer, so as to cover it and fill the openings in the previously developed resin layer.

Alternatively, it is also possible to apply the photoresist of the second resin layer so as to cover the first resin layer without the photoresist penetrating the openings formed at the start of the process. To obtain such a result, a “solid” resin may be used, for example, which could be adhered by lamination.

The second layer of resin is irradiated through the openings of a mask defining the outline of the second level of the desired microstructure. This step requires aligning the mask with the openings of the first level.

A person skilled in the art could also implement 3D printing to deposit the second conductive layer 5.

Such solutions enable a selective and more accurate deposition of the second electrically-conductive layer, and therefore having no deposit over the sidewalls of the photopolymerised resin 3a.

The illustrated next step consists in depositing a second layer of photosensitive resin covering the structure resulting from the previous step. The same resin is used during this step, and the thickness may be larger than that one deposited in step a). In general, the thickness varies according to the geometry of the component to be obtained.

The next step consists in irradiating the second resin layer through a mask defining a second level of the component and dissolving the non-irradiated areas of the second photosensitive resin layer. At the end of this stage, a mould is obtained comprising first and second levels revealing the first electrically-conductive layer 2 and the second electrically-conductive layer in places.

The method of the invention finds a particularly advantageous application in the manufacture of components for timepieces, such as springs, anchors, wheels, etc. Thanks to this method, it is possible to obtain clusters of components that are robust and geometrically reliable.

The method can be used to make an entire cluster on the “wafer” scale or sub-assemblies of mini-clusters on the same wafer. By “wafer”, it should be understood the substrate plate used to form the cluster.

Such a method also allows using the clusters of components in a similar way to the manufacture of components on silicon wafers.

Of course, the present invention is not limited to the illustrated example, i.e. the making of a cam, but is susceptible to various variants and modifications which will become apparent to a person skilled in the art.

1. A method for manufacturing watch components in batches, comprising the following steps:
a) providing a substrate covered with a conductive priming layer;
b) applying a layer of photosensitive resin over the conductive layer of the surface of the substrate;
c) irradiating the resin layer through a mask defining the outline of a batch of components, as well as a grid and material bridges, the material bridges connecting the components to the grid at a non-functional surface, the grid, the material bridges and the watch components forming a cluster of components;
d) dissolving the non-irradiated areas of the photosensitive resin layer to reveal the conductive layer of the substrate in places and form a mould;
e) conformal electro-galvanic deposition of a metal layer from the conductive layer, the metal layer forming the cluster of components and reaching the level of the upper surface of the photosensitive resin layer;
f) removing the photosensitive resin layer and the substrate to release the cluster of components thus formed;
g) releasing the batch of components from the cluster.

2. The method according to claim 1, wherein the method comprises a step e′) between step e) and step f), during which the resin layer and the deposited metal layer are planarised to bring the resin layer and the electrodeposited metal layer to the same level.

3. The method according to claim 1, wherein the method comprises:
after step d), repeating steps c) and d) at least once to obtain a mould with at least two levels;
applying at least one other metal layer to the at least second level of the mould.

4. The method according to claim 1, wherein the mould has several levels.

5. The method according to claim 1, wherein the material bridge has a thickness identical to that of the component.

6. The method according to claim 1, wherein the material bridge has a thickness smaller than that of the component.

7. The manufacturing method according to claim 1, wherein the method comprises a step g) of wafer finishing the front, rear and/or lateral faces of the watch component, the finishing step consisting in depositing layers, for example structuring and/or decorative layers.

8. The method according to claim 1, wherein the cluster of watch components comprises a batch of the same components selected from: wheel, cam, hand, lever, snail, oscillating weight, index or applique.

9. The method according to claim 1, wherein the cluster of watch components comprises a batch of different components such as wheels, cams, hands, levers, oscillating weights, snails, indexes or appliques.

10. A batch of watch components obtained by implementing a method for manufacturing a batch of watch components according to claim 1.
